(19) United States
(12) Patent Application Publication
(10) Pub. No.: US 2008/0257403 A1
(43) Pub. Date: Oct. 23, 2008

(54) PHOTOVOLTAIC WINDOW PANEL WITH HIGH VIEWING TRANSPARENCY

(76) Inventor: Robert Ian Edmonds, Brisbane (AU)

Correspondence Address: BERENATO, WHITE & STAVISH, LLC, 6550 ROCK SPRING DRIVE, SUITE 240, BETHESDA, MD, 20817, US

(21) Appl. No.: 12/121,196

(22) Filed: May 15, 2008

(30) Foreign Application Priority Data
Aug. 9, 2006 (AU) 2006904312
May 16, 2007 (AU) 2007202184

(51) Int. Cl. H01L 31/042

(52) U.S. Cl. 136/251

(57) ABSTRACT

The invention is a photovoltaic window panel comprising a parallel array of strips of photovoltaic cells incorporated within the body of a transparent panel such that the active area or surface plane of a photovoltaic cell is nearly perpendicular to the plane of the transparent panel. The narrow strips of photovoltaic cells are inserted into slots formed in the transparent panel with the strips encapsulated within the slots with a clear potting material. The slotted panel containing the strips of photovoltaic cells is protected by lamination with a clear protective cover. Alternatively the strips of photovoltaic cells may be molded into a panel of transparent material. The electrical outputs of each strip of photovoltaic cells emerge from the two side edges of the transparent panel so that the strips of photovoltaic cells may be connected in parallel or in series to contacts external to the photovoltaic window panel.

This application is a US Utility Application based on Australian Patent Application No. 2007202184 filed May 16, 2007 and is hereby incorporated by reference in it's entirety.

### BACKGROUND OF THE INVENTION

Windows usually form a major proportion of the area of building facades. As such windows provide a large area for solar energy collection. Partly transparent window glazing material coated with photovoltaic (PV) cells has been developed to convert solar energy into electric power. Prior art photovoltaic window glazing takes two forms. One form has very thin (<10 micron thick) and therefore semi-transparent photovoltaic cells coated over substantially all of the window surface, U.S. Pat. No. 5,176,758. The other form has opaque (>10 micron thick) photovoltaic cells covering only part of the window surface, U.S. Pat. No. 6,646,196, U.S. Pat. No. 5,228,925, U.S. Pat. No. 4,137,098, U.S. Pat. No. 4,795,500. FIG. 1 is an illustration of this latter type of prior art photovoltaic window. PV cells, with large surface area, typically 100 mm×100 mm, are encapsulated between two transparent panels. The resulting panel when installed in a window provides shading of the building and electric power. In both cases the active area or surface plane of the PV cells is parallel to the plane of the window. In both cases the PV cells substantially reduce the transmission of light through the window rendering the view through the window darker than it would be with ordinary window glazing or substantially distorted by having significant opaque areas in the window view. Thus a first objective of the present invention is a photovoltaic window panel (PV window panel) that does not significantly reduce the view out of the window. Typically the sunlight transmission or solar heat gain coefficient (SHGC) of prior art PV windows as in FIG. 1 is about 0.3 to 0.8 and depends primarily on the coverage of PV cells over the window surface. As the PV cells in prior art PV windows are co-planar with the window surface the sunlight transmission and SHGC are largely independent of the elevation angle and incidence angle of the sun. Thus in summer when the sun elevation is higher during working hours the SHGC is substantially the same as in winter when the sun elevation is lower during working hours. However, there is a strong case for having windows, the SHGC of which varies from summer to winter, the SHGC ideally being lower in summer and higher in winter. Thus a second objective of the present invention is a PV window panel the SHGC of which is sun elevation dependent such that the SHGC or sunlight transmission is low for higher elevation sunlight (summer) and is higher for lower elevation sunlight (winter).

### SUMMARY OF THE INVENTION

The invention is a photovoltaic window panel comprising a parallel array of strips of photovoltaic cells incorporated within the body of a transparent panel such that the active area or surface plane of a photovoltaic cell is nearly perpendicular to the plane of the transparent panel. The narrow strips of photovoltaic cells are inserted into slots formed in the transparent panel with the strips encapsulated within the slots with a clear potting material. The slotted panel containing the strips of photovoltaic cells is protected by lamination with a clear protective cover. Alternatively the strips of photovoltaic cells may be molded into a panel of transparent material. The electrical outputs of each strip of photovoltaic cells emerge from the two side edges of the transparent panel so that the strips of photovoltaic cells may be connected in parallel or in series to contacts external to the photovoltaic window panel.

### BRIEF DESCRIPTION OF THE DRAWINGS

FIG. 1. Illustration of prior art PV windows in front and side view.

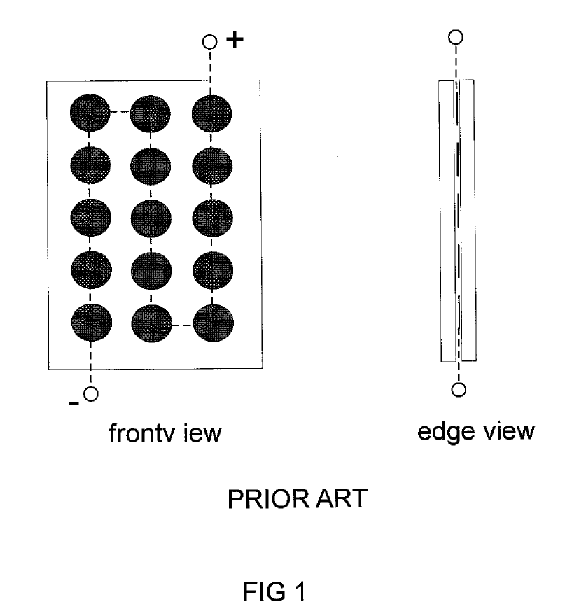

FIG. 2. Illustration of the basic form of the invention in front and side view.

FIG. 3. Illustration of this invention in vertical section, showing narrow strips of PV cells encapsulated in horizontal slots cut in a transparent panel. Also illustrates the refraction of sunlight into the panel.

FIG. 4. Illustration of this invention in vertical section showing typical dimensions of the slots cut in a transparent panel, dimensions of the photovoltaic cells encapsulated in each slot formed in the panel and typical dimension of the protective cover.

FIG. 5. Graph of fraction of sunlight incident on cells versus time of day for Sydney, latitude −34° when the plane of the PV cells is horizontal and is perpendicular to the plane of the PV window panel. The spacing of the slots in the PV window are as in FIG. 4.

FIG. 6. Illustration of the device of this invention with the horizontal slots and the included strips of PV cells at a small angle to the perpendicular to the surface of the panel.

FIG. 7. Graph of the fraction, fa, of sunlight incident on cells versus time of day for Sydney, latitude −34° when cells are included at angle 10° to horizontal and the spacing of the slots is as in FIG. 6.

FIG. 8. Graph of fraction of sunlight incident on cells versus time of day for an East facade window in Sydney, latitude −34° when cells are incorporated at 20° to horizontal and the slot spacing is as in FIG. 6.

FIG. 9. Illustration the increased collection onto bifacial PV cells by adding a reflecting panel external to the PV window panel of this invention.

### DETAILED DESCRIPTION OF THE INVENTION

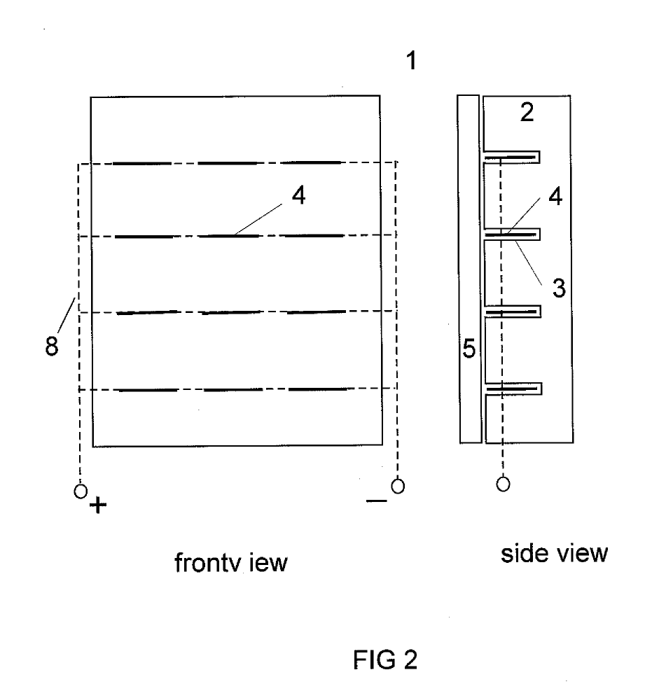

A first embodiment of the photovoltaic window panel 1 is shown in FIG. 2. Narrow strips of PV cells 4 are inserted in slots 3 formed in a transparent panel 2. A transparent cover 5 is laminated to the panel 2 to protect the PV cells encapsulated in the panel. Conducting leads 8 connect the electrical output of the PV cells to output points external to the panel. The view through the PV window of this invention is restricted only by the edge thickness dimension of the strips of PV cells 4 as illustrated in the FRONT VIEW in FIG. 2. As the edge thickness of a strip of PV cells is typically about 0.1 mm and the spacing between the parallel strips of PV cells is typically 5 mm the normal view through the panel or the transparency of the panel is reduced by a fraction of only 1/50 or a percentage of 2%.

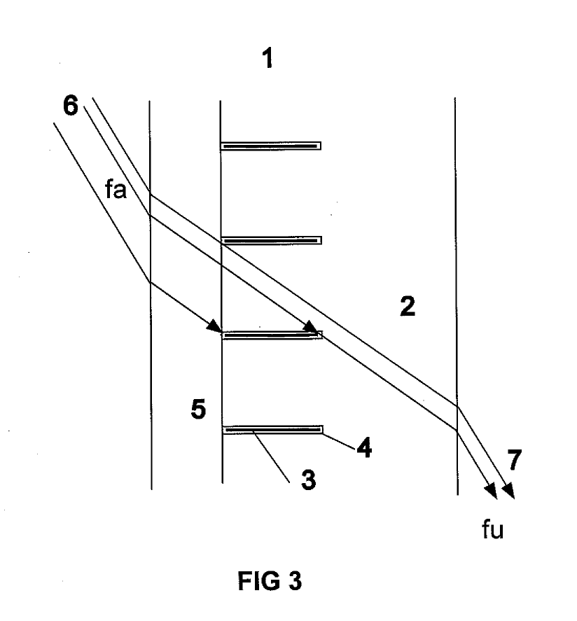

The first embodiment of the invention 1 is also shown in vertical section in FIG. 3. A transparent vertical panel 2 has an array of parallel slots 3 cut into a first face of the panel 2. The slots 3 extend partly through the panel 2. Thin strips of PV cells 4 are inserted in the slots 3 and encapsulated there with a transparent potting material such as EVA or silicone. The slots 3 may be formed in the transparent panel 2 by various means such as milling, laser cutting, water cutting, sawing or by routing. A preferred means of producing a parallel array of slots 3 in a transparent panel 2 is by laser cutting the slots into a major face of a sheet of clear acrylic plastic with an automatic laser cutting machine. FIG. 3 illustrates how a fraction, fa, of the incident sunlight 6 is refracted into the panel to fall on the strips of PV cells 4. The remaining fraction of the incident sunlight, fu, is transmitted through the panel and contributes to the solar heat gain of the building.

In a second embodiment of the invention the transparent panel with parallel slots extending partly through the panel is formed by the process of extruding a clear transparent material such as acrylic plastic resin through an extrusion die. The thin strips of PV cells are encapsulated in the slots so formed in the panel and are protected with a thin transparent panel in the same manner as described in the first embodiment.

In a third embodiment of the invention the strips of PV cells may be incorporated within the body of a transparent panel by the process of molding the transparent panel around the parallel array of strips of PV cells. In this embodiment the parallel array of strips of PV cells is located within a shallow rectangular mold. Molten transparent material such as acrylic plastic resin is poured into the mold and allowed to set thereby incorporating the array of PV cells within a thin panel of transparent material. The conducting leads from the ends of each strip of PV cells are allowed to extend through the sides of the rectangular mold such that when the sides of the mold are removed from the solid panel the leads would extend beyond the sides of the panel and could be connected to provide positive and negative outputs from the photovoltaic window panel.

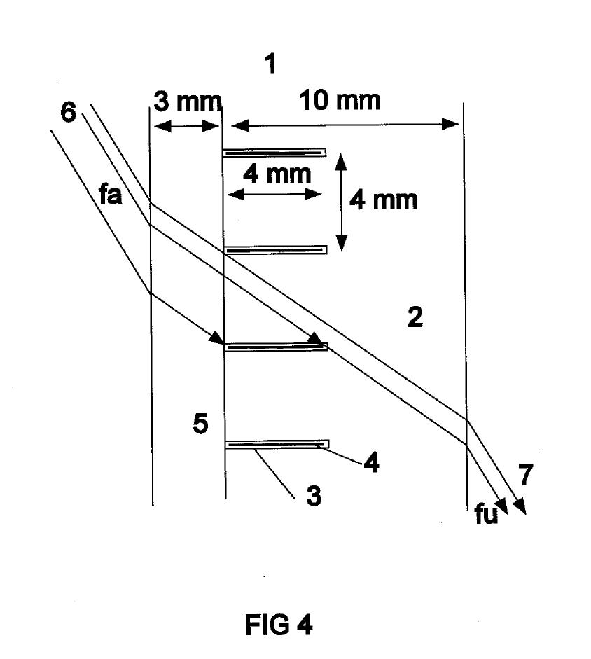

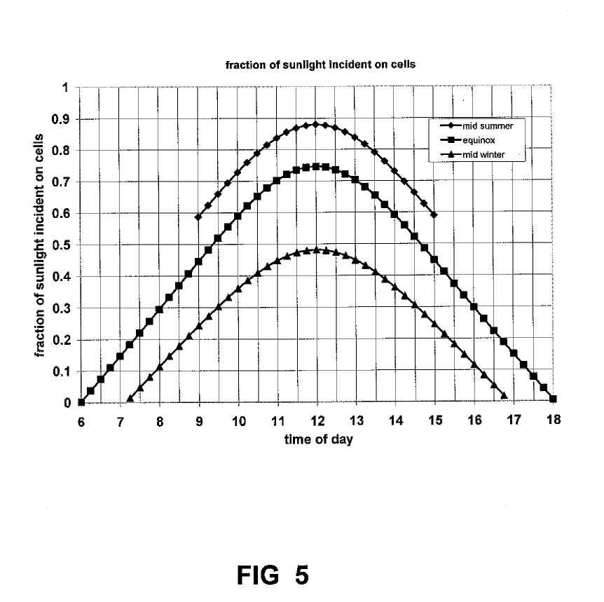

Typical dimensions of the invention 1 are shown in FIG. 4. Aside from the major dimensions shown in FIG. 4 the typical dimensions of the strips of PV cells 4 are 0.1 mm thick, 4 mm wide with each cell in the strip being up to 100 mm long. The overall length of the strip of cells is substantially the same as the width of the PV window panel. PV cells with narrow dimensions are manufactured by the Australian company Origin Energy Ltd (www.originenergy.com.au), are known by the name “Sliver Cells”, and are described in Australian Patent 2002220348. Alternatively the thin strips of PV cells may be in the form thin film PV cells formed on a polymer substrate about 0.05 mm thick as for example the flexible film PV cells manufactured by the U.S. company Powerfilm Solar Ltd. Such thin film PV can be readily cut into a strip of width suitable for incorporation in a panel according to this invention. Typical dimensions of the slots formed in the panel 2 are: the slots are 4 mm deep, 0.2 mm wide and extend continuously across the front surface width of the photovoltaic panel. The viewing transparency is determined mainly by the view through the panel perpendicular to the face of the panel and edge on to the photovoltaic cells and the slots. As the strips of PV cells, typically 0.1 mm thick, occupy only a small fraction 0.1/4=0.025 or 2.5% of the spacing between the strips of PV cells the viewing transparency normal to the face of the panel is reduced by only 2.5% relative to a clear window. FIG. 4 also shows the ray tracing of typical incident sunlight rays 6 through the panel. A fraction, fa, of the sunlight is incident on the photovoltaic cells and is largely absorbed in the cell to produce electrical power and heat. A fraction, fu, of the sunlight 7 passes through the photovoltaic window and into the interior of the building delivering a radiant heat input to the building. The fraction of the incident sunlight that falls on the PV cells is a function of the spacing of the slots in the panel, the width of the strips of PV cells, the refractive index of the material of the panel and the elevation and azimuth angles of the sunlight incident on the panel. Calculations of the fraction, fa, of sunlight incident on the PV cells for the panel geometry given in FIG. 4 are shown in FIG. 5. The fraction, fa, is graphed as a function of time of day and refers to a PV window panel on a Northern facade in Sydney, Australia, latitude −34°. The electrical power output of the PV window panel is proportional to the fraction of sunlight incident on the PV cells, fa. The fraction of sunlight not incident on the cells, fu=(1−fa), is approximately equal to the sunlight transmission of the PV window panel and is also approximately equal to the solar heat gain coefficient (SHGC) of the PV window panel. It is evident from FIG. 5 that in summer the electrical power output is relatively high and the SHGC is relatively low. The converse applies in winter. The dimensions in FIG. 4 are illustrative only. The dimensions can be varied to suit particular applications of the PV window panel.

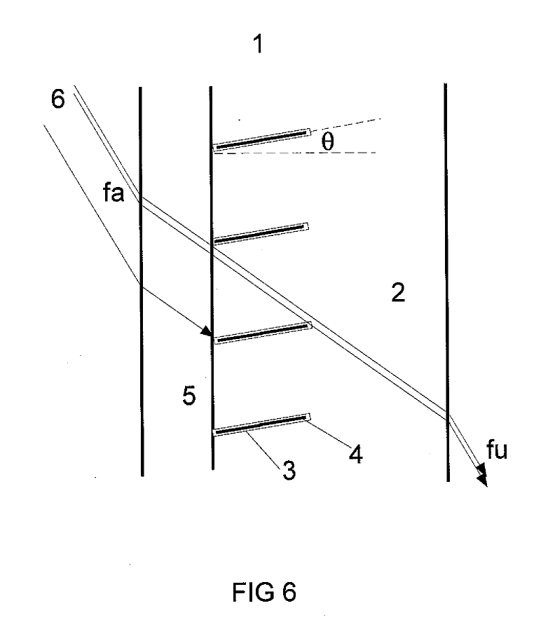

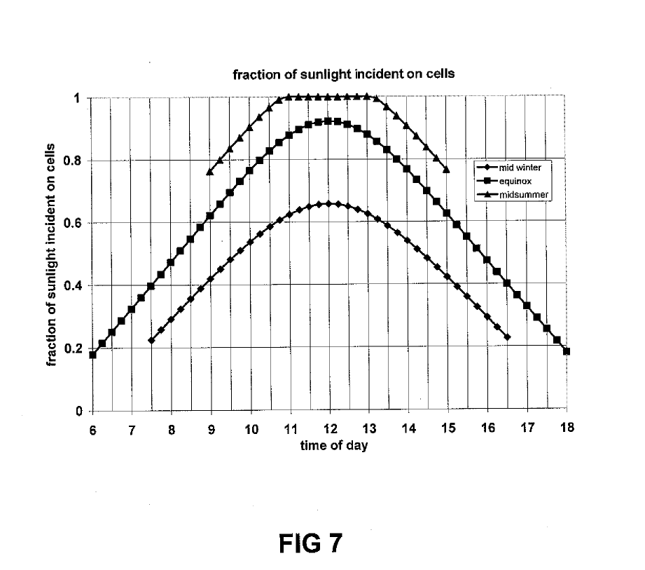

A further variation of the invention 1 is shown in FIG. 6. This variation differs from that shown in FIG. 4 only in having the slots 3 cut in the transparent panel 2 at a small slope angle θ. FIG. 6 illustrates the case when the slope angle is 10 degrees. The viewing transparency normal to the photovoltaic window panel is reduced to 83% while the electrical power output is increased substantially. However, the most common view through a window is in a slightly downward direction and when the cells are sloping downward at a small angle the viewing transparency would be near ideal. The sunlight transmission and the SHGC are decreased substantially relative to the variation in FIG. 4. The effect on performance of a small slope angle of the cells included in the panel is illustrated in FIG. 7. It is evident from a comparison of the graphs in FIG. 7 (slope angle=10°) and FIG. 5 (slope angle=0°) that relatively small changes away from horizontal in the slope angle of the included PV cells has a very significant effect on the electrical power output and SHGC of the PV window panel of this invention. Thus by making a relatively minor variation in the slope angle of the slots formed to include the cells in the panel the performance of the PV window panel of this invention can be tailored to specific requirements of a particular application or latitude location or window orientation.

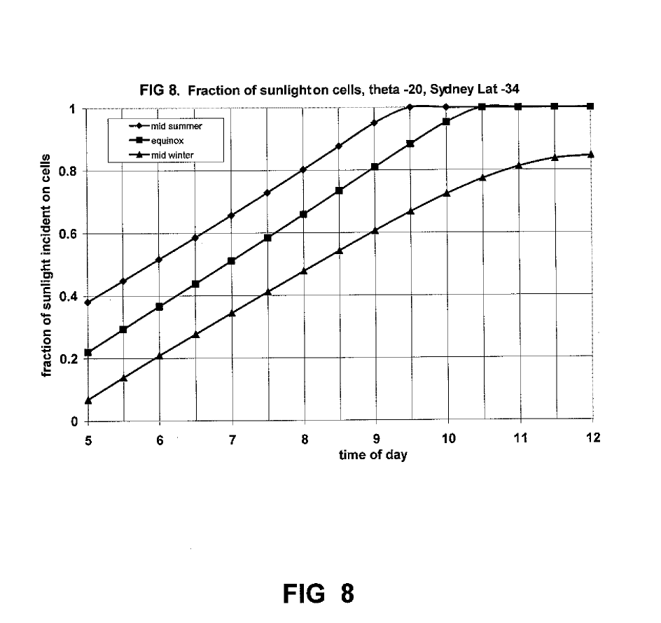

As a further example of a small variation in slope to improve the performance in a quite different window orientation consider the design of the PV window of this invention for an Eastern façade of a building in Sydney. On an Eastern façade it is highly desirable that the SHGC of the window be low during the morning hours between 8 am and 12 noon. A low SHGC can be achieved by increasing the slope angle of the slots and the included PV cells. FIG. 8 shows the calculated fraction, fa, of sunlight incident on the PV cells of a PV window of this invention with dimensions the same as in FIG. 4 but with the slope angle of the included PV cells increased from zero (horizontal) to 20°. FIG. 8 shows that at mid-summer the fraction of the sunlight that is incident on the cells is greater than 80% at all times after 8 am in the morning. Thus the sunlight transmission of the photovoltaic window is expected to be less than 20% during the same period.

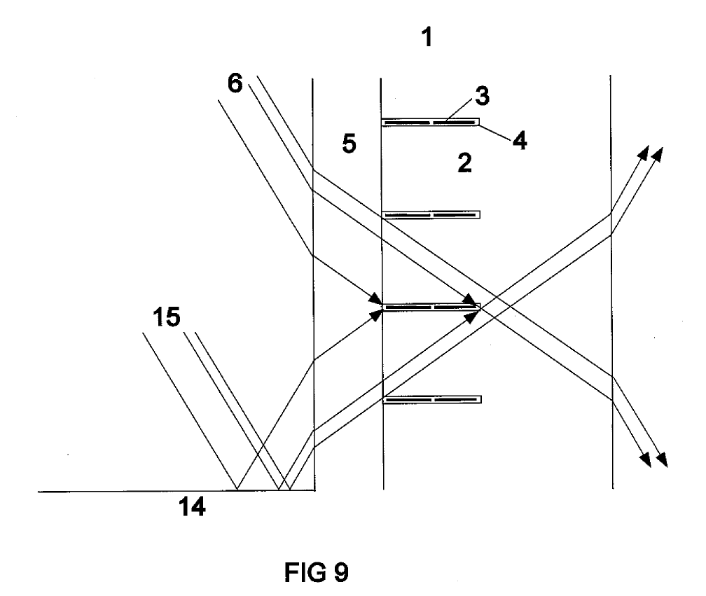

PV cells may be bifacial. For example the “sliver cell” is a bifacial cell. A bifacial cell can convert solar energy incident on both faces of the cell into electrical power. FIG. 9 illustrates that the PV window of this invention has the potential to collect on both surfaces of the PV cells incorporated in the body of the panel by utilizing light reflected from the ground up towards the window or by adding a horizontal reflecting plane 14 external to the window and directly below the PV window of this invention. If the plane 14 is a specular reflector sunlight 15 is reflected onto the PV window and a fraction of this reflected sunlight is incident on the lower face of bifacial cells incorporated in the body of the PV window 1. It is evident that if the reflecting plane 14 is a specular reflector of reflectance ρ the output electrical power is increased by the factor (1+ρ) by the addition of the reflecting plane. In building applications the reflecting plane 14 may be the ground plane external to the building. In such cases the reflectance is mainly diffuse. Nevertheless the bifacial cells in the invention can potentially collect radiation reflected from the ground plane. A reflecting horizontal plane may be introduced as part of the building structure to increase the power output of the bifacial cells in the invention.

Typical dimensions of the PV window of this invention are substantially in the following range: thickness of the panel 2 is in the range 5 mm to 15 mm, depth of the slots 3 is in the range 1 mm to 10 mm. The thickness of protective panel 5 is in the range 1 mm to 10 mm. Typical overall dimensions of the PV window panel of this invention may be vertical height 2.0 m, horizontal width 1.5 m and overall thickness 6 mm −25 mm.

I claim:

1. A photovoltaic window panel comprising a parallel array of narrow strips of photovoltaic cells incorporated within the body of a transparent panel such that the active area or surface plane of the photovoltaic cells is perpendicular to the plane of the major surface of the transparent panel or lies within a narrow angular range of the perpendicular to the plane of the major surface of the transparent panel.

2. A photovoltaic window panel as in claim 1 in which said strips of photovoltaic cells are incorporated within the body of said transparent panel by inserting said strips of photovoltaic cells into parallel slots formed in said transparent panel, said strips of photovoltaic cells being encapsulated within said slots with a clear potting material with a clear transparent cover laminated to said transparent panel to protect the array of strips of photovoltaic cells encapsulated within the body of said transparent panel.

3. A photovoltaic window panel as in claim 2 in which the parallel slots in the transparent panel are formed by using a laser cutting machine to cut the slots into the transparent panel.

4. A photovoltaic panel as in claim 2 in which the parallel slots are formed in said transparent panel by the process of extruding a transparent material such as acrylic or polycarbonate plastic through a die.

5. A photovoltaic window panel as in claim 1 in which the parallel array of strips of photovoltaic cells is incorporated in a transparent panel by molding a transparent plastic panel around the parallel array of strips of photovoltaic cells.

6. A photovoltaic window panel as in claim 1 installed in the window opening of a building such that each strip of photovoltaic cells is parallel to the floor of the building and is parallel to the wall of the building so that the photovoltaic window panel functions (1) to glaze the window opening, (2) to produce electric power by photovoltaic conversion of solar energy incident on the photovoltaic window panel, (3) to provide a view through the photovoltaic window panel to the outside of the building and (4) to reduce the transmission of sunlight through the photovoltaic window panel into the building.
